(19) United States
(12) Patent Application Publication
(10) Pub. No.: US 2003/0112605 A1
(43) Pub. Date: Jun. 19, 2003

(54) Power module and process for producing power modules

(76) Inventor: Wolfram Hable, Neumarkt (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/304,129

(22) Filed: Nov. 25, 2002

(30) Foreign Application Priority Data
Nov. 23, 2001 (DE) 101 57 362.6

(51) Int. Cl. H05K 7/00

(52) U.S. Cl. 361/728

(57) ABSTRACT

A power module has a circuit carrier that, on its upper side is coated with a structured metal layer and mounted with power components. The power components are driven by flat conductors, the inner flat-conductor ends of which interact, via thermocompression heads, with contact-connection surfaces, while the outer flat-conductor ends project out of the housing of the power module. A process is described for producing the power module.

### BACKGROUND OF THE INVENTION

1. Field of the Invention

The invention relates to a power module having an insulation plate, which is coated with metal on both sides, as circuit carrier, and to a process for its production.

Power modules have a plurality of power components on a circuit carrier. The circuit carrier is connected, via adhesively bonded or soldered joins on corresponding contact-connection surfaces of the circuit carrier, to outer flat conductors that project out of a housing of the power module. Power modules of this type involve high costs in production, especially since high-quality, expensive materials are required for adhesively bonded joins in the power module. If the power modules have soldered joins, a high, expensive consumption of energy is required to produce these joins, and the power elements of the power module are exposed to high thermal loads.

2. Summary of the Invention

It is accordingly an object of the invention to provide a power module and a process for producing power modules that overcome the hereinafore-mentioned disadvantages of the heretofore-known devices of this general type and that provides a power module that can be produced at low cost and at low temperatures, and also a process for producing it.

With the foregoing and other objects in view, there is provided, in accordance with the invention, a power module including an insulation plate, a housing, a flat conductor, and a thermocompression head. The insulation plate is coated with metal on both sides, functions as a circuit carrier, has an upper side with a structured metal layer, and has power components mounted on the structured metal layer. The structure metal layer has a contact-connection surface. The housing encases the insulation plate. The flat conductor has an inner flat-conductor end and an outer flat conductor end projecting outside of the housing. The thermocompression head electrically interconnects the flat-conductor end and the contact-connection surface of the structured metal layer.

With the objects of the invention in view, there is also provided a process for producing a power module. The first step of the process is providing a circuit carrier board having contact islands, conductor tracks, and contact-connection surfaces of a structured metal layer in a plurality of module installation positions. The next step is coating at least the contact-connection surfaces with a bondable coating.

The next step is applying thermocompression heads to the contact-connection surfaces. The next step is dividing the circuit carrier board into individual circuit carriers for each module installation position. The next step is providing a system carrier having a system carrier frame. The next step is extending flat conductors with inner flat-conductor ends from the system carrier fame toward a plurality of the module installation positions. The next step is orienting and connecting the thermocompression heads on the contact-connection surfaces of each circuit carrier to the inner flat-conductor ends of each leadframe in the module installation positions of the system carrier. The next step is applying a plurality of power components in each module installation position. The next step is applying bonding connections. The next step is packaging each module installation position of the system carrier together with power components disposed on the circuit carriers in a housing. The next step is dividing the system carrier into individual multichip power modules.

According to the invention, a power module is provided, having an insulation plate, which is coated with metal on both sides, as circuit carrier. On its upper side, the circuit carrier has a structured metal layer and is mounted with power components. Furthermore, the power module has flat conductors, the inner flat-conductor ends of which are electrically connected, via thermo-compression heads, to contact-connection surfaces of the structured metal layer, and the outer flat-conductor ends of which project out of the housing of the power module.

This power module has the advantage that, on account of the electrical and mechanical connection of the inner-flat-conductor ends to the contact-connection surfaces via thermocompression heads, all the known temperature ranges of back-end processes can be withstood mechanically stably and reliably, so that the productivity of production of power modules of this type is improved. The mechanical strength of a join of this type can be increased as desired by suitably matching the number of thermocompression heads per connection to the strength of the join. Furthermore, the current density required for the power modules can be achieved by adapting the number of thermocompression heads per join between inner flat-conductor ends and contact-connection surfaces of the circuit carrier .

Furthermore, a joining process which uses thermo-compression heads has the advantage that it can be used at any desired time during the back-end processes, i.e. may be at the start of a mounting process or may take place at a subsequent time during assembly. This advantage is explained in more detail below with reference to practical examples.

In one embodiment of the invention, the power components on the circuit carrier are connected to one another and/or to the contact-connection surfaces via conductor tracks of the structured metal layer. This embodiment of the invention has the advantage that the cross section of the conductor tracks can be matched to the required densities by using the thickness of the structured metal layer and the width of the conductor tracks in the structured metal layer. The power components may be active power semiconductor chips or may also include passive components, such as resistors, capacitors, and coils. For active power components, it is preferable to use MOS power transistors, IGBT transistors (insulated gate bipolar transistors), power diodes, and/or thyristors.

In a further embodiment of the invention, the electrodes on active upper sides of the power components are connected to the conductor tracks and/or the contact-connection surfaces of the structured metal layer of the circuit carrier via bonding connections. For this purpose, contact surfaces that are connected to the electrodes of the power components are provided on the active upper side of the power components. Sonic and/or thermal energy is used to apply bonding wires to these contact surfaces, leading from the active upper side of the power components to the conductor tracks. This bonding wire technology is also used to connect electrodes of the power components to one another and/or to directly connect the electrodes to the contact-connection surfaces of the circuit carrier. On account of the bonding connections, this results in the possibility of maintaining flexibility in the wiring of the power components on the circuit carrier despite prefabricated structured metal layer.

In a further embodiment of the invention, the circuit carrier has as insulation plate a ceramic plate that may include silicon dioxide, aluminum oxide, silicon nitride, zirconium oxide, magnesium oxide, or silicon carbide or mixtures thereof. Ceramic plates of this type are used in particular for high powers combined, at the same time, with high frequencies as insulation plates for the circuit carrier, since its relative dielectric constant is low.

In a further embodiment of the invention, the circuit carrier has, as insulation plate, a glass fiber-reinforced synthetic resin. Glass fiber-reinforced synthetic resin plates of this type are also known as circuit boards, it being possible for their strength and their dielectric constants to be matched to the requirements of the power module by using the proportion of glass fibers. Insulation plates of this type can be used for low-frequency power modules which are used for controlling motors or are required for mains-operated domestic appliances, since glass fiber-reinforced synthetic resin plates have considerable price advantages over ceramic plates.

In a further embodiment of the invention, it is provided that the circuit carrier has a continuous layer of metal on its underside. This continuous layer of metal on the circuit carrier may at the same time form an outer side of the power module, to which a heat sink can be coupled. Because the thermal conductivity in particular of glass fiber-reinforced synthetic resin plates is not particularly high, a continuous metal layer of this type can on the one hand distribute the heat distribution over the entire area of the synthetic resin plate and on the other hand achieve an improved dissipation of heat via the continuous layer of metal on the underside and therefore on the outer side of the power component.

In a further embodiment of the invention, the metal layers of the circuit carrier include copper or a copper alloy. Copper has the advantage of having a high electrical conductivity and also a high thermal conductivity. The high electrical conductivity is required in particular for the structured metal layer on the upper side of the circuit carrier, while the high thermal conductivity of copper is advantageous in particular for the continuous layer of metal on the underside of the circuit carrier.

To improve the bondability of the copper, in particular of the structured copper layer, in the region of the contact-connection surfaces, in a further embodiment of the invention these contact-connection surfaces may have a bondable coating which is composed of two layers, namely a lower layer including a layer that inhibits copper diffusion and an upper layer including a noble-metal layer. In this case, the lower layer is responsible for ensuring that copper ions cannot diffuse to the upper noble-metal layer and that the bonding connection on the upper side of the contact-connection surface does not become brittle as a result of this diffusion phenomenon. The layer which inhibits copper diffusion includes nickel or a nickel alloy for this purpose, and in particular the contact-connection surface may be covered by a phosphorus-doped nickel coating. A phosphorus-doped nickel coating of this type also has the advantage that a bonding connection can also be produced directly on this nickel coating without the application of a noble-metal alloy.

If the materials used for the bonding wires requires a noble-metal coating on the contact-connection surfaces, this layer includes gold, silver, aluminum, or alloys thereof. Compared to a pure copper surface, these noble-metal layers have the advantage of being insensitive to ambient air and of preventing oxidation of the copper layer. Even a gold or gold-alloy coating with a thickness of a few tens of nanometers is sufficient to achieve this. Therefore, the consumption of pure noble metal for treating the contact-connection surfaces is extremely low and a stable bonding connection is brought about. Furthermore, this process of multilayer coating of the contact-connection surfaces has the advantage that the circuit carrier can be temporarily stored without the contact-connection surfaces being corroded or oxidized.

In a further embodiment of the invention, it is provided that the metal layers on both sides of the circuit carrier have identical coatings that inhibit copper diffusion and/or noble-metal coatings. Identical coatings of this type, both for the structured metal layer on the upper side of the circuit carrier and for the continuous layer of metal on the underside of the system carrier, has the advantage of being associated with a simplification of the process, in that even before the metal layer is structured on the upper side of the circuit carrier, a continuous layer of metal including a first layer of copper or a copper alloy, a second layer including its layer that inhibits copper diffusion and finally a third layer including a noble-metal layer can be applied chemically or by electrodeposition to both sides of an insulation plate. Insulation plates of this type, which have been coated and treated on two sides, for circuit carriers of power modules can be produced at a lower cost than if certain regions on the structured metal layer are to be selectively occupied by a bondable coating.

In a further embodiment of the invention, the thermo-compression heads include gold, aluminum, copper, and/or alloys thereof. Thermocompression heads of this type can be produced relatively inexpensively by thermo-compression bonding on the contact-connection surfaces or on the inner flat-conductor ends, as a result of a suitable tool being used to lower a gold or aluminum wire onto the surfaces with which contact is to be made and as a result of this wire being bonded onto the contact-connection surface or onto the surface of inner flat conductors with the aid of pressure and heat, and as a result of the bonding wire being severed after the production of the bonding heads, without the formation of a bonding wire connection. The number of the thermo-compression heads on the contact-connection surfaces or on the upper sides of the inner flat-conductor ends can be matched to the requirements of the current density and the mechanical strength.

A further embodiment of the invention provides for the flat conductors to include copper or a copper alloy. The flat conductors themselves are part of a system carrier that includes a system carrier frame with a plurality of module installation positions. In each module installation position, flat conductors extend from the system carrier frame to the position of the circuit carrier of a power module. System carriers of this type can be produced at relatively low cost from copper plates or copper foils, so that the material of the flat conductors is also predetermined.

The surfaces may be treated at the inner flat-conductor ends, in order, on the one hand, to prevent diffusion of copper and, on the other hand, to facilitate connection to the thermocompression heads. Therefore, the inner flat-conductor ends may, in a further embodiment of the invention, have a coating which inhibits copper diffusion and/or a noble-metal coating, the composition of which corresponds to the bondable coating on the contact-connection surfaces.

In a further embodiment of the invention, it is provided that the power module is a multichip module with power semiconductor chips disposed on the circuit carrier. In this embodiment of the invention, the power components, where they are power semiconductor chips, are not accommodated in a housing and then mounted on the circuit carrier, but rather are disposed directly on the circuit carrier as semiconductor chips without packaging, making the overall assembly of the power module considerably less expensive.

In a further embodiment of the invention, the power module has a control for an electric motor. Motor controls of this type can control and supply a three-phase motor via the power module. In this case, the power module itself is connected to a single-phase or three-phase mains connection. Power modules of this type for controlling electric motors can also be used for speed control. Finally, power modules of this type also can adapt the power consumption of a three-phase motor by varying the power limit. For this purpose, in a further embodiment of the invention, the power module has an input stage for connection to a single-phase or three-phase mains cable and a three-phase output stage for controlling a three-phase motor.

In a process for producing a power module, first of all a circuit carrier board having contact islands, conductor tracks and contact-connection surfaces of a structured metal layer with a plurality of module installation positions is provided. Then, at least the contact-connection surfaces are provided with a bondable coating. Next, thermocompression heads can be applied to the contact-connection surfaces. After a circuit carrier board has been produced in this way, it is divided into individual circuit carriers for each module installation position.

For further assembly of a power module, a system carrier having a system carrier frame, from which, in each module installation position, flat conductors extend with inner flat-conductor ends in the direction of the circuit carrier that is to be applied, is provided. Then, the thermocompression heads on the contact-connection surfaces of each circuit carrier are oriented and connected to the inner flat-conductor ends of each flat conductor in the module installation position of the system carrier. Finally, a plurality of power components are applied in each module installation position. The power components of each module installation position of the system carrier are packaged together with power components disposed on circuit carriers in a housing, and finally the system carrier is divided into individual multichip power modules.

This process has the advantage that the connections which are able to withstand high temperatures are introduced via thermocompression heads during the process sequence, so that the high-temperature processes for fitting the power components and the temperature change cycles which are required during testing are successfully withstood.

In a further practical example of the process, the sequence of the production steps is changed, in that the connection via thermocompression heads is only made after the power components have been applied to the circuit carrier. In this process variant, the circuit carrier has already been mounted with power components when the thermocompression heads are produced and the thermocompression heads are applied and connected to the contact-connection surfaces. The advantage of this process sequence is that a circuit carrier board for a large number of power modules can first of all be mounted with the power components in a parallel process, and only after this mounting is the circuit carrier board divided into individual circuit carriers.

In a further practical example of the process, an insulation plate which has been laminated with copper on two sides is provided as circuit carrier. This insulation plate, which has been laminated with copper on two sides, may already include a further metal layer of a layer which inhibits copper diffusion and a noble-metal layer. The insulation plate that has been laminated with copper on two sides is then structured on a single side with contact islands for fixing power semiconductor chips, with conductor tracks and with contact-connection surfaces. The opposite copper layer is retained as a continuous layer of metal.

In a further embodiment of the process, the patterning of the metal layer can be carried out by etching through an etching mask. Etching of this type may include wet-etching or dry-etching through an etching mask. A further possible option for structuring the layer of metal on the upper side of the circuit carrier includes the possibility of laser ablation, which can be carried out selectively by laser scanning without the need for a preparatory mask. If a bondable coating is applied in the form of a layer which inhibits copper diffusion and then a noble-metal layer including gold, silver or alloys thereof is applied, electrolytic deposition has proven appropriate for this application, since it can be carried out over a large surface area for a circuit carrier board which has already been laminated with copper on both sides.

A further possible option includes using stencil printing to apply a layer of phosphorus-doped nickel as the layer that inhibits copper diffusion; at the same time, this layer can also be used as bondable coating. Stencil printing has the advantage that this layer which inhibits copper diffusion can be applied selectively to the contact-connection surfaces even after the structuring of the metal layer on the upper side of the circuit carrier.

In a further practical example of the process, it is provided that the thermocompression heads are applied to the inner flat-conductor ends and/or to the coated contact-connection surfaces by using thermocompression bonding or thermocompression ultrasonic bonding. Both the application to the contact-connection surfaces of a circuit carrier board and the application of the thermocompression heads to the inner flat conductors before inner flat-conductor ends are combined with the circuit carriers have advantages. In both cases, the required number of thermocompression heads can be applied in parallel for a large number of power modules.

In a further practical example of the process, the power semiconductor chips are electrically connected and mechanically fixed to the contact islands of the circuit carrier in each module installation position of the system carrier by soldering. A soldering technique of this type has the advantage of being highly reliable and therefore achieving a high service life for the power component, and can be used both prior to the fitting of the thermocompression heads and after the fitting of the thermocompression heads. On the other hand, it is possible for the power semi-conductor chips to be electrically connected and mechanically fixed to the contact islands of the circuit carrier with the aid of a conductive adhesive. This process variant provides for extremely low temperatures, since only a slight increase in temperature in order to crosslink the adhesive to form a thermoset is required in order to cure the adhesive. Because the adhesive-bonding process entails lower costs than the soldering process, the adhesive-bonding process is used if inexpensive power modules which are exposed to lower operating loads are to be produced.

In a further practical example of the process, the electrodes on the active upper sides of the power semiconductor chip can be electrically connected to one another and/or to the conductor tracks of the structured metal layer of the circuit carrier via bonding connections. The advantages of this process are the high flexibility of the circuit structuring, which may even take place after power semiconductor chips have been mounted on the circuit carrier.

In principle, each power module can be accommodated in a housing made from a plastic filled with silicone gel, but in many cases it is advantageous for the casing to be produced by a plastics injection-molding process known as transfer molding, because in this way the bonding wires, the semiconductor chips and also the thermocompression heads of the connection of inner flat-conductor ends and contact-connection surfaces are simultaneously protected and mechanically stabilized by this plastic housing.

The dividing of the system carrier, which includes a plurality of module installation positions, into individual multichip power modules may take place at the end of packaging of the power modules in a plastic housing by stamping. This is because stamping has the advantage that at the same time as the separating of the outer flat conductors, which project out of the housing, from the system carrier frame, the outer flat-conductor ends can be bent over and their spatial configuration can be matched to the planned application.

To summarize, it can be stated that the invention is based on a “stud bump” process. This “stud bump” process is a thermocompression process in which a partially melted drop of bonding wire is pressed onto a metal surface and is then torn off. The thermocompression heads are also known as nail heads. In this “nail head” process or thermocompression process, contact-making bumps, known as bumps, are formed, for example from a gold alloy. Then, the circuit carrier board can be “flicked” or turned and electrically connected to corresponding flat conductors of a leadframe with of temperature, ultrasound, and pressure. A certain number of these bumps are applied to the underside of the leadframe or to the upper side of circuit carrier, in each case at the contact-connection surfaces provided for this purpose. The leadframe and the circuit carrier are aligned together and are permanently joined to one another by heat, ultrasound, and pressure. This join is mechanically stable within the temperature range which is of relevance for all known back-end processes. The number of bumps per contact-connection surface is defined by the mechanical strength required of the join and/or by the current density required in the join. The joining process itself may take place either right at the start of the mounting process or at a later time during the assembly process.

Other features that are considered as characteristic for the invention are set forth in the appended claims.

Although the invention is illustrated and described herein as embodied in a power module and a process for producing power modules, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic sectional view showing a power module according to a first embodiment of the invention;

FIG. 2 is a diagrammatic sectional view showing a circuit carrier for a power module with thermocompression heads on contact-connection surfaces prior to the application of inner flat-conductor ends;

FIG. 3 is a diagrammatic sectional view through a circuit carrier of a power module before the application of inner flat-conductor ends that have been provided with thermocompression heads;

FIG. 4 is a diagrammatic sectional view through a circuit carrier mounted with power components for a power module before the application of inner flat-conduction ends that have been provided with thermocompression heads;

FIG. 5 is a diagrammatic sectional view through a circuit carrier that has been mounted with power components for a power module with thermocompression heads on contact-connection surfaces prior to the application of inner flat-conductor ends;

FIG. 6 is a diagrammatic sectional view through a power module after the electrical and mechanical connection of contact-connection surfaces of the circuit carrier with inner flat-conductor ends prior to packaging in a housing; and

FIG. 7 is a diagrammatic plan view of a module component position of a system carrier with flat conductors and of a circuit carrier which has been electrically and mechanically connected to inner flat-conductor ends in the module installation position via thermo-compression heads and mounted with power components, before packaging in a housing.

### DESCRIPTION OF THE PREFERRED EMBODIMENTS

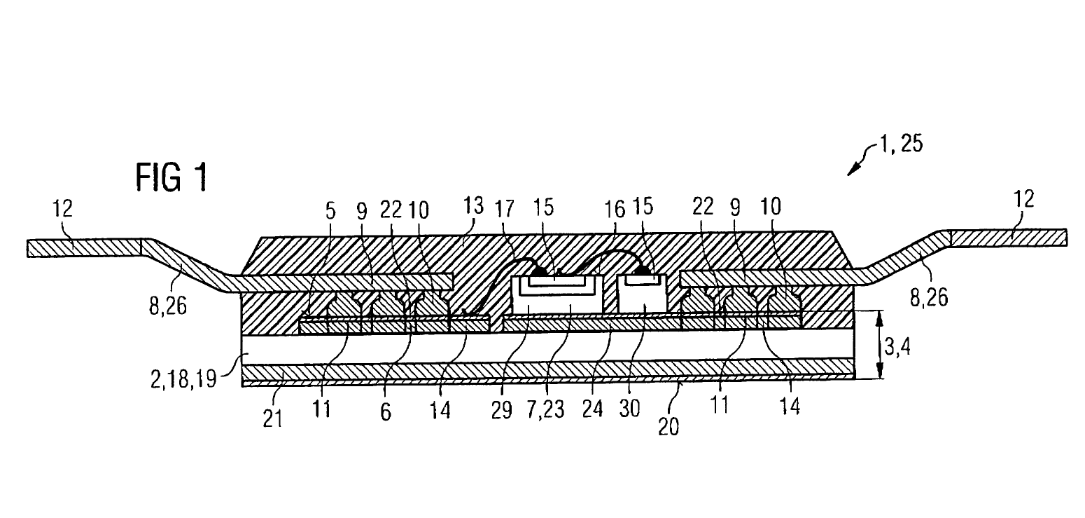

Referring now to the figures of the drawings in detail and first, particularly to FIG. 1 thereof, there is shown a diagrammatic cross section through a power module 1 according to a first embodiment of the invention. Reference numeral 2 denotes an insulation plate that forms the mechanical base plate of a circuit carrier 3. This circuit carrier 3 may have been separated from a circuit carrier board 4 that includes a plurality of circuit carriers 3. Reference numeral 5 denotes the upper side of the circuit carrier 3 or of the circuit carrier board 4, a structured metal layer 6 being disposed on this upper side 5. Reference numeral 7 denotes power components, which in this embodiment are power semiconductor chips 23, the power components 7 being disposed on the contact islands 24. In this embodiment of the invention, in this cross section, a power transistor 29 and a power diode 30 are disposed on a common contact island 24, which is connected to a contact-connection surface 11 on the circuit carrier 3 via a conductor track 14. Therefore, the cathode of the power diode 30 and the collector of the power transistor 29 are electrically connected to one another, and, furthermore, the emitter of the power transistor 29 and the anode of the power diode 30 are connected via bonding connections 17. Reference numeral 8 denotes a flat conductor, the outer flat-conductor end 12 of which projects out of the housing 13 of the power module 1, and the inner flat-conductor end 9 of which is connected to the contact-connection surface 11 via thermocompression heads 10.

In this embodiment of the invention, three thermo-compression heads are disposed between the inner flat-conductor end and the contact surface 11. This number of three thermocompression heads is sufficient to satisfy the demands both on the current density and on the mechanical strength for this power module. The outer flat-conductor ends, which project out of the housing, are slightly bent in order to facilitate attachment to a printed-circuit board disposed above.

Reference numeral 15 denotes the electrodes of the power semiconductor chip 23, the transistor having at least two electrodes 15 on its active upper side, namely an emitter electrode and a base electrode of a bipolar power transistor, and the power diode 30 having at least one electrode, namely the anode, on the active upper side.

The outer flat-conductor end of this cross section on the right-hand side of FIG. 1 is electrically connected, via the inner flat-conductor ends 9, the thermocompression heads 10, the contact-connection surfaces 11, the conductor tracks 14 and the contact islands 24, to the cathode of the power diode 30 and the collector of the power transistor 29. The flat conductor 8 on the left-hand side of this cross-sectional illustration is connected, via the inner flat-conductor end 9 and the thermocompression heads 10, the contact-connection surface 11 and the conductor track 14 and also the bonding connection 17, to the emitter of the power transistor 29. The flat conductors 8 are part of a system carrier 26, which includes a plurality of module installation positions 25, from which the power module 1 as shown in FIG. 1 has been stamped. During this stamping of the power module 1, the outer flat-conductor ends 12 are bent at the same time.

Reference numeral 20 denotes the underside of the circuit carrier 3, which is covered by a continuous layer of metal 21. This continuous layer of metal 21 on the underside 20 of the circuit carrier 3 at the same time forms the underside of the power module. This configuration has the advantage that the heat that is generated in the power components 7 can be dissipated via this layer of metal. To enhance the dissipation of heat and therefore the cooling, this layer of metal may be connected to a heat sink or heat-conducting block. A power module 1 of this type is extremely reliable, because the connection between inner flat conductors 9 and contact-connection surfaces 11 via thermocompression heads 10 ensures mechanically stable and electrically reliable linking of the power semiconductor chips 23 packaged in the plastic housing material to the flat conductors 8.

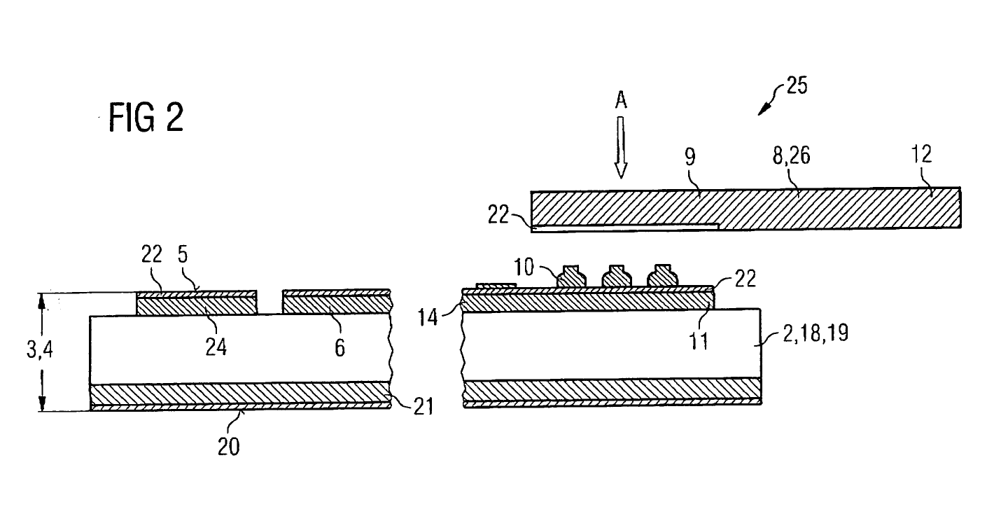

FIG. 2 shows a diagrammatic cross section through a circuit carrier 3 for a power module with thermocompression heads 10 on contact-connection surfaces 11 before the application of inner flat-conductor ends 9. Components that have the same function as in FIG. 1 are denoted by identical reference numerals and are not provided with any extra explanation.

The circuit carrier 3, which is part of a circuit carrier board 4 and has been separated therefrom, substantially includes a ceramic plate 18, which is composed of silicon dioxide, aluminum oxide, zirconium oxide, magnesium oxide, or silicon carbide or mixtures thereof. On its underside, this ceramic plate has a continuous layer of metal 21, which at the same time forms the underside of the future power module. A structured metal layer 6, which substantially includes copper or a copper alloy and is coated with a bondable coating 22, has been applied to the upper side 5 of the circuit carrier board 4. This bondable coating 22 may include a single layer of phosphorus-doped nickel, the phosphorus content being between 5 and 10% by weight.

This layer, which inhibits copper diffusion, prevents copper ions from being able to diffuse to the thermocompression heads 10, where they could make the bonding connection more brittle. On its surface 5, the circuit carrier 3 does not yet have any power semiconductor chips, but does already have thermocompression heads 10 disposed on its contact-connection surface 11. The inner flat-conductor end 9 is applied to these thermocompression heads 10, in the direction indicated by arrow A, at elevated temperature, pressure and with ultrasound using the thermocompression process. For this purpose, the inner flat-conductor end 9 may likewise be equipped with a bondable coating 22. This bondable coating 22 includes a layer that inhibits copper diffusion and a noble-metal layer facilitates the bonding of the flat-conductor ends to the thermo-compression heads 10 of the circuit carrier 3.

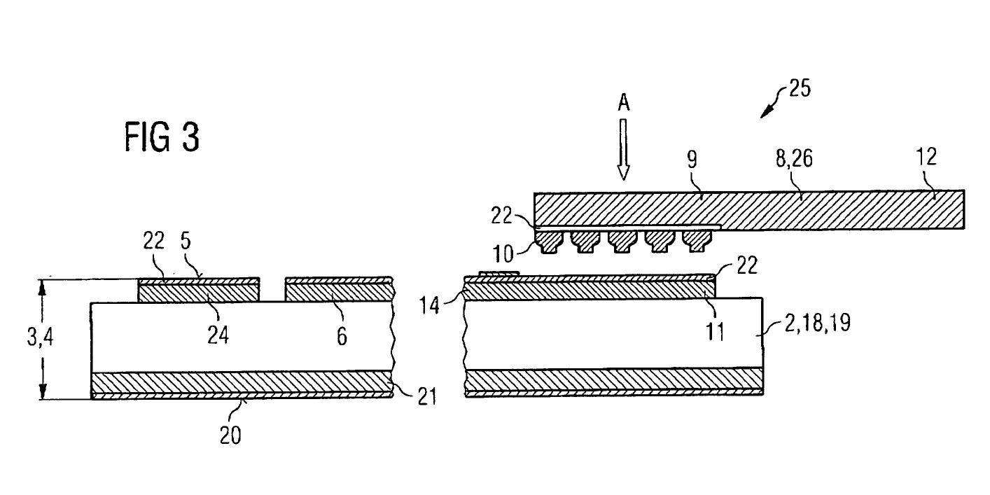

FIG. 3 shows a diagrammatic cross section through a circuit carrier 3 of a power module prior to the application of inner flat-conductor ends 9 that have been provided with thermocompression heads 10. Components having the same function as in the previous figures are denoted by identical reference numerals and are not provided with any additional explanation.

In the embodiment shown in FIG. 3 too, the circuit carrier 3 has not yet been mounted with power semiconductor chips and on its surface only has a structured metal layer 22, which substantially includes chip islands 24, conductor tracks 14, and contact-connection surfaces 11. Unlike in the embodiment shown in FIG. 2, in this embodiment the thermocompression heads 10 are firstly bonded to the inner flat-conductor ends and therefore to the system carrier 26, which includes a plurality of module installation positions 24 and consequently has a multiplicity of flat conductors and inner flat-conductor ends 9, which can be provided with thermocompression heads 10 in parallel. Then, a suitably prepared circuit carrier 3, which does not have any thermocompression heads on its contact-connection surfaces 11, in each of the module installation positions 25 can be mechanically and electrically connected to the inner flat-conductor ends 9 which have thermocompression heads 10, as a result of the inner flat-conductor ends 9 being bonded onto the contact-connection surfaces 11 in the direction indicated by arrow A.

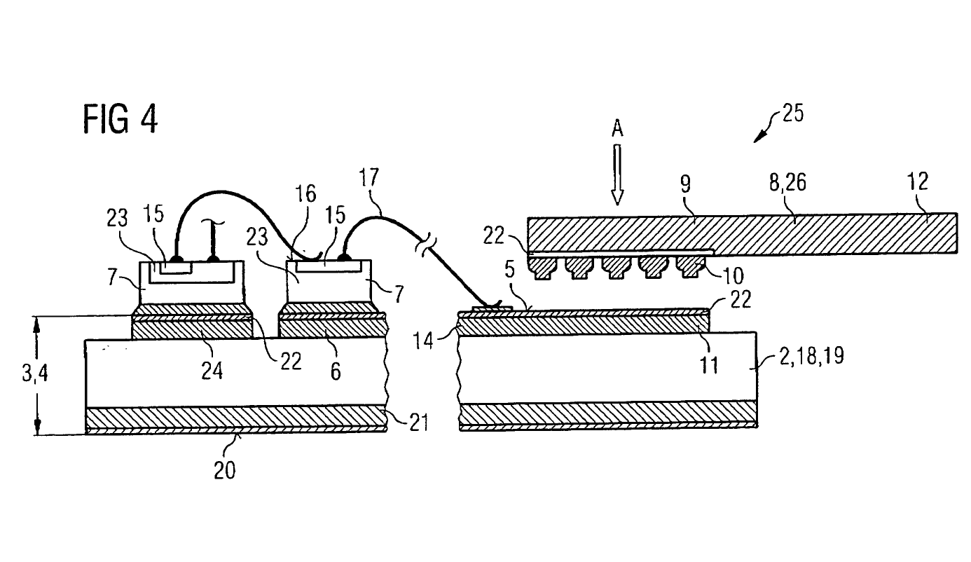

FIG. 4 shows a diagrammatic cross section through a circuit carrier 3, which has been mounted with power components 7, for a power module before the application of inner flat-conductor ends 9 that have been provided with thermocompression heads 10. Components that have the same functions as in the previous figures are denoted by identical reference numerals and are not provided with any additional explanation.

In this embodiment of the invention shown in FIG. 4, first of all a circuit carrier board 4 is completely produced in full size for a plurality of circuit carriers 3, i.e. in each individual position of the circuit carriers 3 it is mounted with power semiconductor chips 23, and the electrodes of the power semiconductor chips are electrically connected either to one another or to the conductor tracks 14 via bonding connections. Only then is the circuit carrier board 4, which includes a plurality of circuit carriers 3, moved into a module installation position 25 of a system carrier 24, where it is bonded to the prepared inner flat conductors 9, which are already mounted with thermocompression heads 10. For this purpose, the flat-conductor ends of the system carrier can once again be lowered in the direction indicated by arrow A, or conversely the circuit carrier together with the semiconductor chips and the bonding connections can be moved toward the system carrier.

Unlike in the previous embodiments shown in FIGS. 1 and 2, this embodiment of the invention has five thermocompression heads per join, in order to ensure a higher current density and a greater mechanical strength.

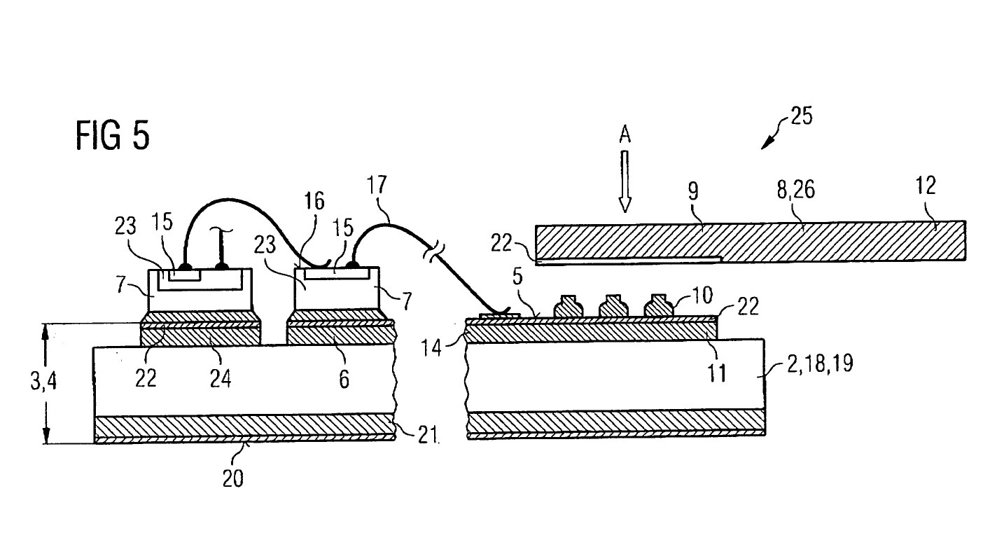

FIG. 5 shows a diagrammatic cross section through a circuit carrier 3, which has been mounted with power components 7, for a power module with thermocompression heads 10 on contact-connection surfaces 11 prior to the application of inner flat-conductor ends 9. Components that have the same functions as in the previous Figures are denoted by identical reference numerals and are not provided with any additional explanation.

In this embodiment shown in FIG. 5, unlike in the embodiment shown in FIG. 4, the circuit carrier 3 is provided with thermocompression heads 10 on the contact-connection surfaces 11, so that the circuit carrier 3 can be moved toward the inner flat-conductor ends 9, in order to produce a bonding connection via the thermocompression heads 10 to the inner flat conductors 9. Unlike in the embodiments shown in FIGS. 2 and 3, this embodiment of FIG. 5 already has the components of the power module on the system carrier 3, and these components have also already been completely wired by bonding connections, and consequently the application of the inner flat-conductor ends to the contact-connection surfaces takes place immediately prior to the packaging of the power module in a housing.

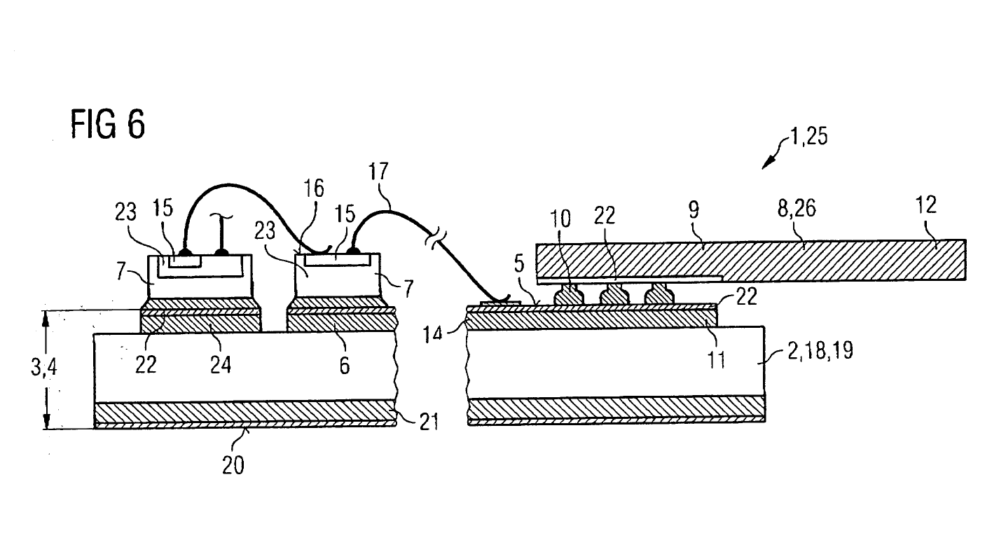

FIG. 6 shows a diagrammatic cross section through a power module 1 after the electrical and mechanical connection of contact-connection surfaces 11 of the circuit carrier 3 to inner flat-conductor ends 9 before packaging in a housing. Components with identical functions to those in the previous figures are denoted by identical reference numerals and are not provided with any additional explanation.

FIG. 6 in principle shows the result of the process steps shown in FIGS. 2, 3, 4, and 5, but in FIG. 6 this result is limited to three thermocompression heads 10 and does not show five thermocompression heads, as in FIGS. 3 and 4. It can be seen from this figure that the power module can be matched to the demands imposed on the mechanical strength and electrical current density in the region of the connection between inner flat conductors 9 and contact-connection surfaces 11 by controlling the number of thermocompression heads. The difference with respect to the cross section through a power module illustrated in FIG. 1 is that in FIG. 1 the flat conductors project out of the housing on both sides, while in FIG. 6 they can only project out of the housing on one side.

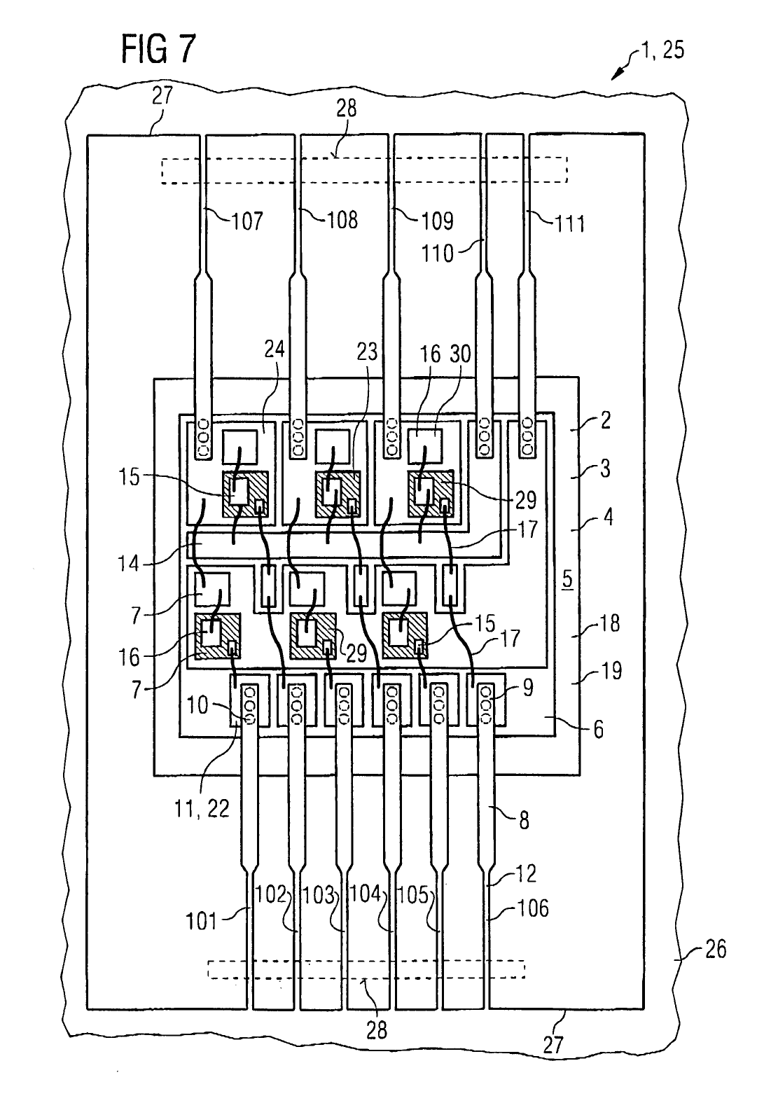

FIG. 7 shows a diagrammatic plan view of a module installation position of a system carrier 26 with flat conductors 8 and of a circuit carrier 3, which is electrically and mechanically connected to inner flat-conductor ends 9 in the module installation position 25 via thermocompression heads 10 and is mounted with power components 23, prior to packaging in a housing. Components with identical functions to those in the previous figures are denoted by identical reference numerals and are not provided with any additional explanation.

In the illustration shown in FIG. 7, the circuit carrier with the power components 7 is disposed below the system carrier 26. FIG. 7 only illustrates one of the module installation positions 25 of a system carrier 26, each module installation position 25 being surrounded by a system carrier frame 27, from which flat conductors 8 extend toward the center of the system carrier frame 27. The outer end 12 of the flat conductors 8 is secured to the system carrier frame, and the inner flat-conductor ends 9 of the flat conductors 8 project beyond the circuit carrier 3.

Dashed line 28 indicates the stamping track in which a stamping tool stamps the power module out of the system carrier frame as soon as this power module has been packaged in a housing in the module installation position 25. The thermocompression heads 10, which are disposed between the circuit carrier 3 with its contact-connection surfaces 11 and the inner flat-conductor ends 9 are illustrated by dashed lines in the illustration shown in FIG. 7. This embodiment shown in FIG. 7 includes a “six-pack” component, which includes six power transistors 29, which are driven via six outer flat conductors 101, 102, 103, 104, 105, and 106 and interact with six power diodes 30.

I claim:

1. A power module, comprising:
an insulation plate coated with metal on both sides, functioning as a circuit carrier, having an upper side with a structured metal layer, and having power components mounted on said structured metal layer, said structured metal layer having a contact-connection surface;
a housing encasing said insulation plate;
a flat conductor having an inner flat-conductor end and an outer flat conductor end projecting outside of said housing; and
a thermocompression head electrically interconnecting said flat-conductor end and said contact-connection surface of said structured metal layer.

2. The power module according to claim 1, wherein said structured metal layer has conductor tracks connecting at least one of said power components to one another and said power components to said contact-connection surfaces.

3. The power module according to claim 2, wherein said power components have active upper sides; and
electrodes disposed on said active upper sides are connected to at least one of said conductor tracks and said contact-connection surface of said structured metal layer via bonding connections.

4. The power module according to claim 1, wherein said insulation plate of said circuit carrier is a ceramic plate including a compound selected from the group consisting of SiO₂, A1₂O₃, Si₃N₄, ZrO₂, MgO, and SiC.

5. The power module according to claim 1, wherein said insulation plate of said circuit carrier is a glass-fiber-reinforced synthetic resin.

6. The power module according to claim 1, wherein said circuit carrier has an underside; and
a continuous layer of metal is disposed on said underside of said circuit carrier.

7. The power module according to claim 1, wherein said metal layer of said circuit carrier includes a copper-containing metal selected from the group consisting of copper and a copper alloy.

8. The power module according to claim 1, further comprising a bondable coating disposed on said contact-connection surface and supporting said thermocompression head.

9. The power module according to claim 8, wherein said bondable coating includes at least one of a layer inhibiting copper diffusion and a noble-metal layer.

10. The power module according to claim 9, wherein said layer inhibiting copper diffusion includes a nickel-containing metal selected from the group consisting of nickel and a nickel alloy.

11. The power module according to claim 9 wherein said noble-metal layer includes a metal selected from the group consisting of gold, silver, aluminum, and alloys thereof.

12. The power module according to claim 1, wherein said contact-connection surface includes a phosphorus-doped nickel coating.

13. The power module according to claim 9, wherein said layer inhibiting copper diffusion of said contact-connection surface has a gold-containing coating having a thickness on the order of tens of nanometers, said gold-containing coating being made from a material selected from the group consisting of gold and a gold alloy.

14. The power module according to claim 1, wherein said metal on both sides of said circuit carrier has identical coatings selected from the group consisting of a copper-diffusion inhibiting layer and a noble-metal coating.

15. The power module according to claim 1, wherein said thermocompression head include a metal selected from the group consisting of gold, aluminum, copper, and alloys thereof.

16. The power module according to claim 1, wherein said flat conductors includes a copper-containing metal selected from the group consisting of copper and a copper alloy.

17. The power module according to claim 8, wherein said inner flat-conductor end has a coating selected from the group consisting of a layer inhibiting copper diffusion and a noble-metal coating, said coating having a composition corresponding to said bondable coating on said contact-connection surface.

18. The power modules according to claim 1, wherein said power components are power semiconductor chips disposed on said circuit carrier.

19. The power module according to claim 1, wherein at least one of said power components forms a control for an electric motor.

20. A process for producing a power module, which comprises the steps:
providing a circuit carrier board having contact islands, conductor tracks, and contact-connection surfaces of a structured metal layer in a plurality of module installation positions;
coating at least the contact-connection surfaces with a bondable coating;
applying thermocompression heads to the contact-connection surfaces;
dividing the circuit carrier board into individual circuit carriers for each module installation position;
providing a system carrier having a system carrier frame;
extending flat conductors with inner flat-conductor ends from the system carrier frame toward a plurality of the module installation positions;
orienting and connecting the thermocompression heads on the contact-connection surfaces of each circuit carrier to the inner flat-conductor ends of each leadframe in the module installation positions of the system carrier;
applying a plurality of power components in each module installation position;
applying bonding connections to the power components;
packaging each module installation position of the system carrier together with power components disposed on the circuit carriers in a housing; and
dividing the system carrier into individual multichip power modules.

21. The process according to claim 20, which further comprises:
laminating an insulation plate with copper on two sides;
using the insulation plate as circuit carrier;
structuring one of the copper layers to include contact islands for fixing the power semi-conductor chips, with conductor tracks (13) and contact-connection surfaces; and
retaining the opposite copper layer as a continuous metal layer.

22. The process according to claim 20, wherein the metal layer is structured by etching through an etching mask.

23. The process according to claim 22, wherein the etching is dry etching.

24. The process according to claim 22, wherein the etching is wet etching.

25. The process according to claim 20, wherein the metal layer is structured by laser ablation.

26. The process according to claim 20, wherein the bondable coating is formed by
first applying a layer inhibiting copper diffusion; and
then applying a metal layer selected from the group consisting of gold, silver, and an alloy thereof, by electrolytic deposition.

27. The process according to claim 26, wherein the applying a layer inhibiting copper diffusion includes stencil printing a layer of phosphorus-doped nickel.

28. The process according to claim 20, which further comprises applying the thermocompression heads to at least one of the inner flat-conductor ends and the coated contact-connection surfaces by a bonding method selected from the group consisting of thermocompression bonding and thermocompression sonic bonding.

29. The process according to claim 20, which further comprises soldering the power semiconductor chips to the contact islands of the circuit carrier in each module installation position of the system carrier to electrically connect and mechanically fix the power semiconductor chips to the contact islands.

30. The process according to claim 20, which further comprises mechanically fixing by adhesively bonding the power semiconductor chips to the contact islands of the circuit carrier in each module installation position of the system carrier.

31. The process according to claim 20, which further comprises mechanically fixing by conductively and adhesively bonding the power semiconductor chips to the contact islands of the circuit carrier in each module installation position of the system carrier.

32. The process according to claim 20, which further comprises electrically connecting the electrodes on the active upper sides of the power semiconductor chip to at least one of one another and the conductor tracks of the structured metal layer, via bonding connections.

33. The process according to claim 20, wherein the packaging step of each module installation position in a housing includes high-pressure injection molding to form a plastic housing.

34. The process according to claim 20, wherein the dividing of the system carrier into individual multichip power modules includes stamping the system carrier.

35. A process for producing a power module, which comprises the following process steps:
providing a circuit carrier board having a plurality of module installation positions including contact islands, conductor tracks, and contact-connection surfaces of a structured metal layer;
selectively coating the contact-connection surfaces with a bondable coating;
mounting a plurality of power components on the circuit carrier board in each module installation position;
applying bonding connections in each module installation position;
applying thermocompression heads to the contact-connection surfaces;
dividing the circuit carrier board into individual circuit carriers for each module installation position;
providing a system carrier having a system carrier frame;
extending flat conductors with inner flat-conductor ends toward a plurality of the module installation positions;
orienting and connecting the thermocompression heads on the contact-connection surfaces of each circuit carrier to the inner flat-conductor ends of each leadframe in the module installation positions of the system carrier;
packaging each module installation position of the system carrier together with power components disposed on circuit carriers in a housing; and
dividing the system carrier into individual multichip power modules.

36. The process according to claim 35, which further comprises:
laminating an insulation plate with copper on two sides;
using the insulation plate as circuit carrier;
structuring one of the copper layers with contact islands for fixing the power semi-conductor chips, with conductor tracks and contact-connection surfaces; and
retaining the opposite copper layer as a continuous metal layer.

37. The process according to claim 35, wherein the metal layer is structured by etching through an etching mask.

38. The process according to claim 37, wherein the etching is dry etching.

39. The process according to claim 37, wherein the etching is wet etching.

40. The process according to claim 35, wherein the metal layer is structured by laser ablation.

41. The process according to claim 35, wherein the bondable coating is formed by
first applying a layer inhibiting copper diffusion; and
then applying a metal layer selected from the group consisting of gold, silver, and an alloy thereof, by electrolytic deposition.

42. The process according to claim 41, wherein the applying a layer inhibiting copper diffusion includes stencil printing a layer of phosphorus-doped nickel.

43. The process according to claim 35, which further comprises applying the thermocompression heads to at least one of the inner flat-conductor ends and the coated contact-connection surfaces by a bonding method selected from the group consisting of thermocompression bonding and thermocompression sonic bonding.

44. The process according to claim 35, which further comprises soldering the power semiconductor chips to the contact islands of the circuit carrier in each module installation position of the system carrier to electrically connect and mechanically fix the power semiconductor chips to the contact islands.

45. The process according to claim 35, which further comprises mechanically fixing by adhesively bonding the power semiconductor chips to the contact islands of the circuit carrier in each module installation position of the system carrier.

46. The process according to claim 35, which further comprises mechanically fixing by conductively and adhesively bonding the power semiconductor chips to the contact islands of the circuit carrier in each module installation position of the system carrier.

47. The process according to claim 35, which further comprises electrically connecting the electrodes on the active upper sides of the power semiconductor chip to at least one of one another and the conductor tracks of the structured metal layer, via bonding connections.

48. The process according to claim 35, wherein the packaging step of each module installation position in a housing includes high-pressure injection molding to form a plastic housing.

49. The process according to claim 35, wherein the dividing of the system carrier into individual multichip power modules includes stamping the system carrier.
